(19) United States
(12) Patent Application Publication
(10) Pub. No.: US 2026/0206549 A1
(43) Pub. Date: Jul. 16, 2026

(54) METHOD FOR POST GAS DEVELOPMENT TREATMENT OF METAL OXIDE PHOTORESIST

(71) Applicant: Tokyo Electron Limited, Tokyo (JP)

(72) Inventors: Hamed Hajibabaeinajafabadi, Albany, NY (US); Subhadeep Kal, Albany, NY (US)

(21) Appl. No.: 19/018,795

(22) Filed: Jan. 13, 2025

(51) Int. Cl. H01L 21/033; G03F 7/42; H01L 21/027

(52) U.S. Cl. CPC H10P 76/4085; G03F 7/42; H10P 76/2041; H10P 76/405; H10P 76/4083

(57) ABSTRACT

A method for processing a substrate includes receiving the substrate including a metal oxide photoresist (MOR) layer disposed over an underlying layer, the MOR layer including a first region and a second region. The method further includes performing a gas development treatment on the MOR layer to remove portions of the first region. And the method further includes exposing the MOR layer to a gas mixture to remove remaining portions of the first region after the gas development treatment to form a patterned MOR mask.

### TECHNICAL FIELD

The present invention relates generally to semiconductor manufacturing, and, in particular embodiments, to a system and method for post-gas development treatments of metal oxide photoresists (MORs).

### BACKGROUND

In the semiconductor industry, photolithography is commonly used in the fabrication of integrated circuits, with metal oxide photoresists (MOR) emerging as a valuable material for advanced patterning processes due to their high resolution and etch resistance properties. Traditionally, photoresists are developed using wet chemical processes. However, gas-based development techniques have gained attention for their potential to achieve finer features and reduce pattern collapse. In gas development of MOR, a gas or vapor is used to selectively remove exposed or unexposed areas of the photoresist, creating the desired pattern. This process involves complex interactions between the development chemistry and the metal oxide components of the photoresist.

### SUMMARY

In accordance with an embodiment of this disclosure, a method for processing a substrate includes receiving the substrate including a metal oxide photoresist (MOR) layer disposed over an underlying layer, the MOR layer including a first region and a second region. The method further includes performing a gas development treatment on the MOR layer to remove portions of the first region. And the method further includes exposing the MOR layer to a gas mixture to remove remaining portions of the first region after the gas development treatment to form a patterned MOR mask.

In accordance with another embodiment of this disclosure, a method for processing a substrate includes receiving the substrate in a processing chamber, the substrate including a metal oxide photoresist (MOR) layer disposed over an underlying layer, the substrate having been treated in a gas development process, the MOR layer including a first region and a second region. The method further includes setting the processing chamber to a processing pressure and heating the substrate to a first processing temperature, and exposing the MOR layer to a gas mixture by flowing the gas mixture into the processing chamber at a flow rate for a processing time, the gas mixture adsorbing to the first region of the MOR layer to form a chemically altered first region. And the method further includes heating the substrate to a second processing temperature to remove the chemically altered first region and form a patterned MOR mask, the second processing temperature being greater than the first processing temperature.

And in accordance with yet another embodiment of this disclosure, a system for processing a substrate includes a substrate holder disposed in a processing chamber, a vacuum pump, a gas distribution system, a temperature control system coupled to the substrate holder, and a controller coupled to the gas distribution system, the vacuum pump, the temperature control system, and a memory storing instructions to be executed by the controller. The instructions when executed cause the controller to receive the substrate on the substrate holder, the substrate including a MOR layer disposed over an underlying layer, the substrate having been treated in a gas development process, the MOR layer including a first region and a second region, and set the processing chamber to a processing pressure using the vacuum pump and heating the substrate to a first processing temperature using the temperature control system. The instructions when executed further cause the controller to expose the MOR layer to a gas mixture by flowing the gas mixture into the processing chamber at a flow rate for a processing time using the gas distribution system, the gas mixture adsorbing to the first region of the MOR layer to form a chemically altered first region, and heat the substrate to a second processing temperature using the temperature control system to remove the chemically altered first region and form a patterned MOR mask.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1E illustrate a substrate during various steps of a processing method to remove undesired portions of a metal oxide photoresist layer in accordance with an embodiment of this disclosure;

FIGS. 2A-2B illustrate a substrate during various steps of the processing method to remove undesired portions of a metal oxide photoresist layer in accordance with an embodiment of this disclosure;

FIG. 3 is a flowchart illustrating the steps of a processing method to remove undesired portions of a metal oxide photoresist layer in accordance with an embodiment of this disclosure;

FIG. 4 is a system diagram of a processing system capable of implementing the processing method for removing undesired portions of a metal oxide photoresist layer in accordance with an embodiment of this disclosure;

FIG. 5 is a flowchart illustrating a processing method for removing undesired portions of a metal oxide photoresist layer in accordance with an embodiment of this disclosure; and

FIG. 6 is a flowchart illustrating a processing method for removing undesired portions of a metal oxide photoresist layer in accordance with an embodiment of this disclosure.

### DETAILED DESCRIPTION OF ILLUSTRATIVE EMBODIMENTS

In the field of semiconductor manufacturing, metal oxide photoresists (MOR) are utilized for patterning processes. Gas development techniques are employed to reveal patterns in these photoresists. However, the current gas development processes for MOR face several challenges. Incomplete development, residue formation, and scumming during gas development can lead to an increase in defects and remaining material on the substrate. After the gas development process, additional challenges arise, such as outgassing and tin contamination. These challenges can negatively impact the quality and reliability of the resulting semiconductor devices. Existing approaches to address these challenges often rely on plasma treatments for the removal of bromine and reduction of outgassing. However, plasma treatments have limitations due to their non-selective nature, as they use reactive radicals and energetic photons that can potentially damage or alter the desired patterns.

This disclosure describes a post-treatment process to address the challenges associated with metal oxide photoresist (MOR) development. In various embodiments, the post-treatment process employs a combination of hardware and specific chemistries to complete the gas development of MOR and reduce outgassing during subsequent transfer steps. The post-treatment process may utilize a separate processing chamber from the gas development step, such as a gas chamber, as a secondary chamber following the main development chamber. In one or more embodiments, the post-treatment process may utilize the same processing chamber as the gas development step. In an embodiment, the post-treatment applies coordinating chemistries, such as hexafluoroacetylacetone (HFAC), acetylacetone (ACAC), organic acids, diols, thiols, or alcohols. In those embodiments, a coordinated bromine (Br) group may be replaced with organic functional groups. The post-treatment is performed within a temperature range of 35° C. to 300° C. and at pressures between 20 and 90,000 mTorr. This method reduces residue, improves selectivity, and minimizes contamination. In one or more embodiments, the post-treatment process can be integrated into existing workflows with minimal impact on throughput. Additionally, X-ray photoelectron spectroscopy (XPS) composition analysis indicates that the post-treatment may lead to a reduction in bromine content and adsorption of treatment chemicals on exposed areas, resulting in decreased outgassing while maintaining consistent tin levels in the MOR.

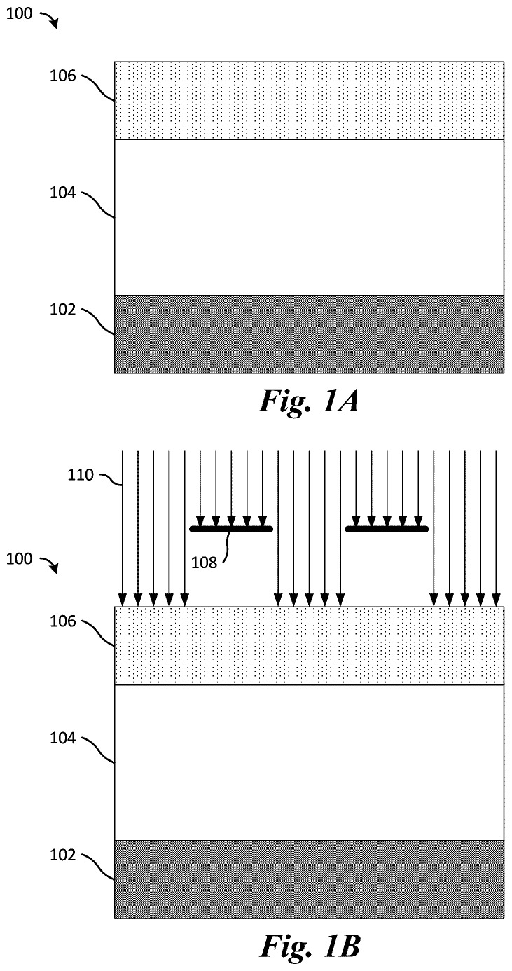

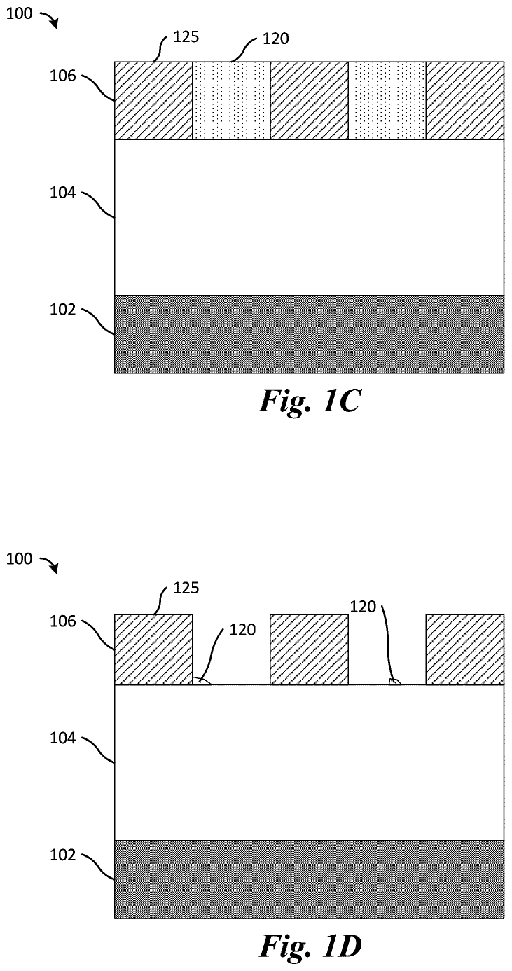

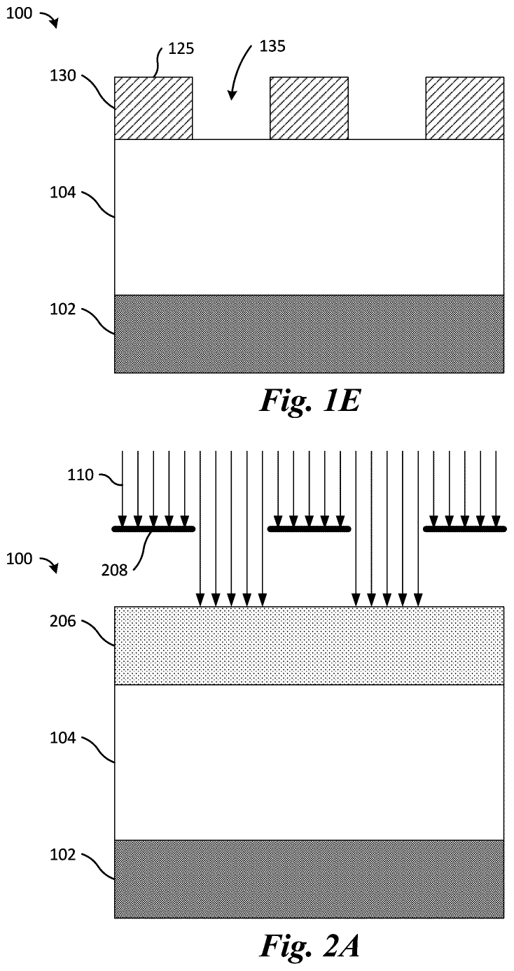

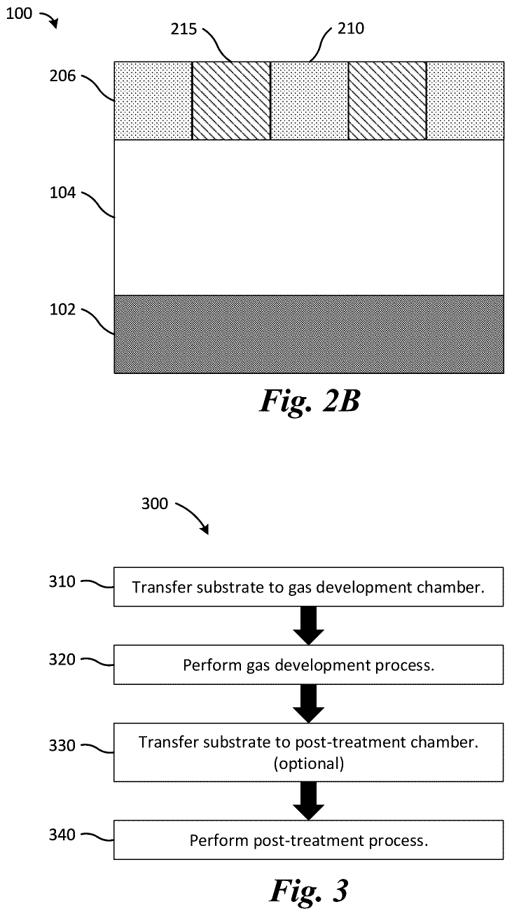

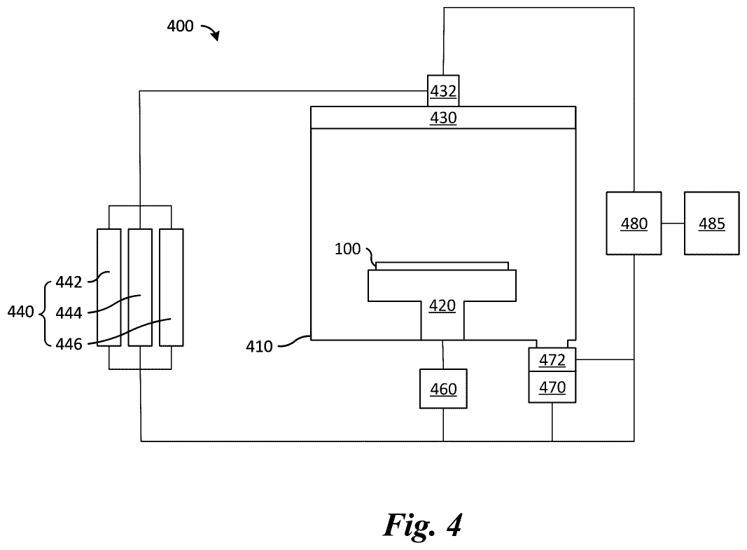

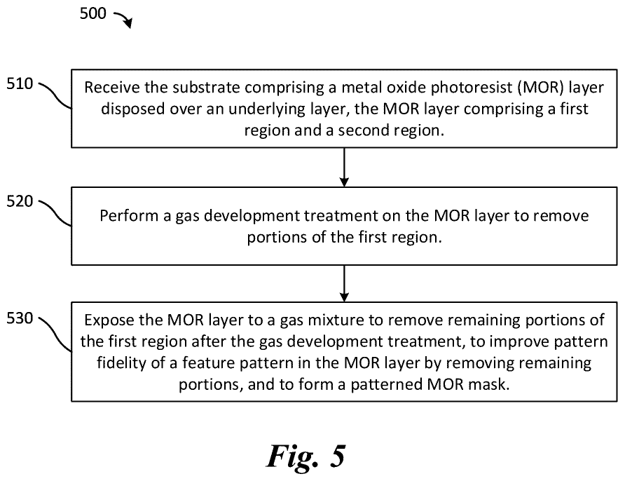

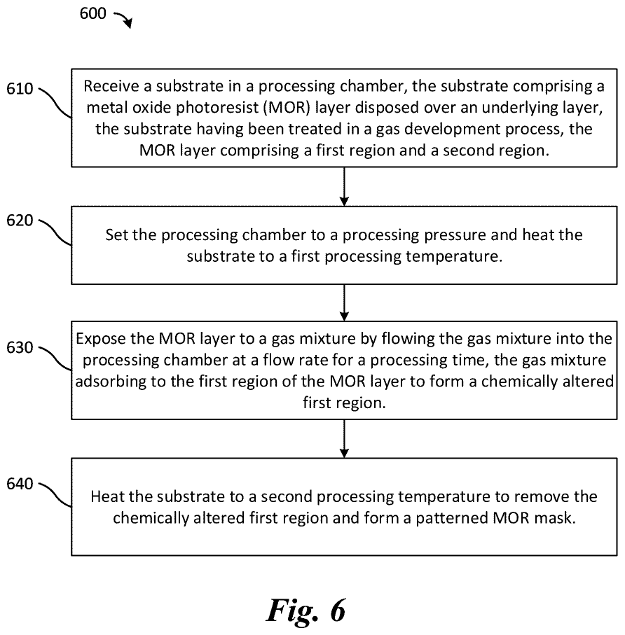

Embodiments provided below describe various methods, apparatuses and systems for processing a substrate, and in particular, to methods, apparatuses, and systems that use a post-treatment process to remove remaining portions of a metal oxide photoresist after a gas development step. The following description describes the embodiments. FIGS. 1A-1E describe an example processing method for developing a negative tune metal oxide photoresist layer comprising a post-treatment step. FIGS. 2A-2B describe an embodiment of the processing method when the substrate comprises a positive tune metal oxide photoresist layer. FIG. 3 is a flowchart used to describe the processing method comprising a post-treatment step of this disclosure. An example system capable of implementing the post-treatment step of the processing method of this disclosure is described using FIG. 4. And the flowcharts of FIGS. 5-6 illustrate two other example processing methods comprising a post-treatment step for the removal of remaining portions of the metal oxide photoresist layer in accordance with embodiments of this disclosure.

FIGS. 1A-1E illustrate a substrate 100 during various steps of a processing method which may be used to remove undesired portions of a metal oxide photoresist layer in accordance with an embodiment of this disclosure.

FIG. 1A illustrates a cross-sectional view of a substrate 100 which may be used in the processing method of this disclosure. The substrate 100 comprises a substrate base 102, an underlying layer 104 disposed over the substrate base 102, and a metal oxide photoresist (MOR) layer 106 disposed over the underlying layer 104. In an embodiment, the substrate 100 illustrated in FIG. 1A may be after receiving the substrate 100 in a photolithography tool to develop the MOR layer 106.

The underlying layer 104 and the MOR layer 106 may have been deposited through conventional deposition methods before the substrate 100 is received in the photolithography tool. For example, the underlying layer 104 may be deposited through a suitable deposition process such as a plasma deposition process, or an atomic layer deposition (ALD) process, or a chemical vapor deposition (CVD), or a plasma-enhanced chemical vapor deposition (PECVD) process. In various embodiments, after depositing the underlying layer 104, a planarization process may be performed to planarize the underlying layer 104 before depositing the MOR layer 106. Further, the MOR layer 106 may be deposited through a suitable deposition process for the MOR layer 106 such as a spin coating method, or gas phase deposition techniques such as an ALD/MLD process or a CVD process.

The substrate base 102 may comprise silicon, silicon oxide, or other suitable materials commonly used in semiconductor manufacturing. In various embodiments, the underlying layer 104 may comprise various materials depending on the specific application, such as dielectric materials, conductive materials, or semiconductor materials. For example, the underlying layer 104 may comprise a film stack for forming a memory device. In various embodiments, the underlying layer 104 may have a pattern transferred into it through a suitable etching process in subsequent processing steps. The MOR layer 106 comprises a photosensitive material that can be patterned through exposure to light, and subsequently used as a mask for further processing steps after patterning. In various embodiments, the MOR layer 106 comprises tin (Sn), oxygen/hydroxide (O/OH), oxygen (O), or organic components (saturated/unsaturated hydrocarbon). As an example, various embodiments of the MOR layer 106 comprise tin oxide, hafnium based MORs (such as hafnium oxide), zirconium based MORs (such as zirconium oxide), titanium based MORs (such as titanium oxide), or mixed metal MORs (such as hafnium zirconium oxide).

In various embodiments, the MOR layer 106 may be negative tune metal oxide photoresists, which may strengthen when exposed to patterning light such that regions exposed to the patterning light are more difficult to remove. In other embodiments, the MOR layer 106 may be positive tune metal oxide photoresists, which may weaken when exposed to patterning light such that regions exposed to the patterning light are easier to remove, such as described using FIGS. 2A-2B below. FIGS. 1A-1E illustrate embodiments where the MOR layer 106 comprises negative tune MOR.

As described above, the substrate 100 depicted in FIG. 1A may represent an initial stage in a photolithography process, where the MOR layer 106 is yet to be exposed to patterning light. This configuration forms the basis for subsequent processing steps, which may comprise exposure, development, and post-treatment (which may also be followed by etching) to create desired patterns on the substrate 100.

FIG. 1B illustrates the next step in the processing method, where conventional techniques are employed to develop the MOR layer 106 shown in FIG. 1A through exposure to light beams 110. In the step illustrated in FIG. 1B, a photo mask 108 is positioned above the substrate 100. The photo mask 108 comprises a predetermined pattern (feature pattern) that will be transferred to the MOR layer 106.

In various embodiments, light beams 110 are directed towards the photo mask 108. These light beams 110 may comprise ultraviolet (UV) light, extreme ultraviolet (EUV) light, or other suitable wavelengths depending on the photolithography process. In various embodiments where the light beams 110 comprise UV light, the photo mask 108 selectively blocks or allows the passage of light beams 110, creating a pattern of exposed and unexposed regions on the MOR layer 106. In other embodiments where the light beams 110 comprise EUV light, the photo mask 108 selectively reflects or allows the passage of light beams 110, creating the pattern of exposed and unexposed regions on the MOR layer 106.

The light beams 110 that pass through the photo mask 108 interact with the MOR layer 106, initiating photochemical reactions in the exposed regions. This interaction alters the chemical properties of the exposed regions, making them either stronger or weaker for a subsequent development process, depending on whether the MOR is a positive tune or negative tune resist. In the embodiment illustrated in FIG. 1B, the MOR layer 106 comprises negative tune MOR, which makes the exposed regions more difficult to remove after the exposure to the light beams 110.

In an embodiment, the exposure time and intensity of the light beams 110 are carefully controlled to ensure proper patterning of the MOR layer 106. The precise control of these parameters helps achieve the desired resolution and fidelity of the pattern transfer process.

FIG. 1C depicts the substrate 100 following the light exposure of the previously unexposed MOR layer 106. This step illustrates the outcome of the photolithography process illustrated in FIG. 1B. The substrate 100 now comprises a patterned structure resulting from the selective light exposure of the MOR layer 106.

In one or more embodiments, the exposure to the patterning light in FIG. 1B formed a first region and a second region in the MOR layer, where the first region is an unexposed MOR region 120, and where the second region is an exposed MOR region 125. These exposed MOR regions 125 correspond to areas of the MOR layer 106 that were exposed to the light beams 110. The unexposed MOR regions 120 correspond to areas of the MOR layer 106 that were protected by the opaque parts of the photo mask 108 during the light exposure step.

The unexposed MOR regions 120 (the first regions) and exposed MOR regions 125 (the second regions) may be used to create a feature pattern on the substrate 100 that mirrors the design of the photo mask 108 used in the previous step. In various embodiments, the feature pattern may represent features such as trenches, vias, or other structures suitable for the functionality of the final device. After the light exposure, a post exposure bake (PEB) may be performed using temperatures between 160° C. and 250° C. for a timeframe between 15 s and 300 s. Additionally, the PEB may be performed at pressures between 10 mTorr and 10 Torr in an inert gas atmosphere of Ar or N₂.

The processing method illustrated by FIGS. 1A-1E uses a gas development process to remove the first regions (the unexposed MOR regions 120) to form the feature pattern in the MOR layer 106, which is described using FIG. 1D below.

FIG. 1D illustrates the substrate 100 following a conventional gas development process applied to remove undesired portions of the MOR layer 106. This stage represents a further refinement of the feature pattern started in the previous photolithography steps where portions of the underlying layer 104 are now exposed, but remnant, scumming, or byproducts of the unexposed MOR regions 120 remain. Different amounts of scumming, remnants (remaining portions), or byproducts of the unexposed MOR regions 120 may remain after the gas development process based on the sizes of the features (such as their critical dimensions (CD)) in the desired feature pattern of the MOR layer 106.

In various embodiments, the gas development process involves exposing the substrate 100 to a reactive gas or gas mixture. In various embodiments, the gas or gas mixture comprises organic acids (such as acetic acid) and inorganic Lewis acids (such as hydrogen halides comprising HBr) and/or Bronsted acid. This gas interacts with the undesired portions of the MOR layer 106 to chemically alter a first region (or the unexposed MOR region 120) of the MOR layer 106, facilitating their removal from the substrate surface. The process selectively targets the unexposed MOR regions 120 while leaving the exposed MOR regions 125 largely intact. The selectivity of the gas mixture used in the gas development process enables the targeted removal of either the exposed MOR regions 125 or unexposed MOR regions 120 as desired. Though the gas development process uses a selective gas mixture to remove desired portions of the MOR layer 106, the process may still remove undesired portions, just at a slower rate. The selectivity refers to removing the undesired portions of the MOR layer 106 at a faster rate than desired portions.

The gas development process results in a more defined feature pattern on the substrate 100. The exposed MOR regions 125 now stand out more prominently, forming a mask that can be used for subsequent processing steps. In an embodiment, the spaces between the exposed MOR regions 125 may reveal the underlying layer 104, creating openings that may be utilized for further etching or deposition processes. Conventional processing methods for MOR layers perform just the gas development step described above, but the processing method of this disclosure adds a post-treatment process to remove any remnants of the unexposed MOR region 120 across features with different aspect ratio across the entire wafer to fully reveal the underlying layer 104 and improve the fidelity of the feature pattern in the MOR layer 106.

During the gas development process, factors such as gas composition, pressure, temperature, and exposure time are carefully controlled to achieve optimal pattern resolution and minimize potential damage to the MOR layer 106. In one or more embodiments, the gas used may comprise halogen-containing compounds, oxygen-based gases, or other reactive species depending on the specific chemistry of the MOR layer 106. In other embodiments, the gas used may comprise nitrogen, hydrogen, and the gas may be exposed to the MOR layer 106 at a first temperature to chemically alter a surface region of the MOR layer 106. After, the substrate 100 may be brought to a second temperature to remove the chemically treated surface region of the MOR layer 106.

This gas development step enhances the overall quality of the patterned MOR layer by removing undesired regions (or portions) of the MOR layer 106 after the photolithography and improving the edge definition of the exposed MOR regions 125. However, the gas development process described using FIG. 1D may still leave some residues or result in incomplete development in certain areas (wide areas with low aspect ratio), which can affect subsequent processing steps. For example, as illustrated in FIG. 1D, the gas development process did not completely remove the unexposed MOR regions 120, which may remain from scumming products (which may be MOR material from the MOR layer 106) or residue accumulation.

When the unexposed MOR regions 120 are not completely removed, defects may form in subsequent processing steps of the fabrication process, such as a subsequent etching step. Additionally, outgassing from the MOR layer 106 may continue after the gas development process. To address these challenges, the processing method of this disclosure comprises a post-treatment to remove remaining portions of the unexposed MOR regions 120 and prevent outgassing in subsequent steps. The post-treatment process may be described using FIG. 1E below.

FIG. 1E depicts the substrate 100 after undergoing a post-treatment process designed to remove any remaining portions of the unexposed MOR regions 120 of the MOR layer 106 that were not fully removed by the gas development process illustrated in FIG. 1D. This step is a refinement of the patterning process, aiming to achieve a cleaner and more precise pattern on the substrate surface.

In various embodiments, the post-treatment process employs a combination of specific chemistries and controlled environmental conditions to target and remove residual MOR material and prevent outgassing from the substrate 100 during subsequent transfers to other processing. This post-treatment process results in a patterned MOR mask 130 with improved definition and clarity compared to the structure shown in FIG. 1D. Further, the post-treatment process may be performed in a separate processing chamber than the gas development process, such as the post-treatment processing chamber described using FIG. 4.

The patterned MOR mask 130 comprises the exposed MOR regions 125 and now exhibits well-defined openings 135 that extend down to the underlying layer 104. These openings 135 correspond to the areas where the undesired MOR material has been completely removed, creating a clear path to the underlying layer 104. In one or more embodiments, the size and shape of these openings 135 closely match the intended pattern (feature pattern) from the original photo mask 108 used in the exposure step (FIG. 1B).

The post-treatment process comprises the use of coordinating chemistries, such as a chelating agent comprising oxygen as a coordinating atom which may be used to form a chelate complex after bonding with a metal ion. In various embodiments, the chelating agent may comprise acetylacetone (ACAC); ACAC derivatives comprising various degrees of halgenations (halogen: F, Cl, Br) such as hexafluoroacetylacetone (HFAC); organic acids such as acetic acid, formic acid, and derivatives comprising various degrees of halogenation (mono-, di-, and tri-halogen; halogen: F, Cl, Br); halogenated analogues such as triflic acid; or simple alcohols such as methanol, ethanol, and isopropyl alcohol; or a combination of aforementioned chemistries. These chemicals interact with the residual MOR material of the unexposed MOR regions 120, facilitating its removal by bonding with metal ions of the residual MOR material without significantly affecting the patterned MOR mask 130. Further, remnants and scumming products may both be removed in the post-treatment process as a result of the remnants and scumming products both comprising residual MOR material from the MOR layer 106. In an embodiment, the post-treatment process may be performed in a controlled environment with specific temperature and pressure conditions, typically ranging from 35° C. to 300° C. and 20 mTorr to 90,000 mTorr, respectively.

This post-treatment step addresses challenges associated with conventional gas development processes, such as incomplete development, residue formation, outgassing, and scumming (such as photoresist scumming). By thoroughly removing the residual MOR material and byproducts, the post-treatment process prevents defects, improves pattern fidelity, and prepares the substrate 100 for subsequent processing steps, such as etching or material deposition. Additionally, through the complete removal of the remaining undesired MOR material and byproducts from the MOR layer 106, outgassing may be prevented, which also prevents contamination of other substrates in transfer to another processing chamber.

In various embodiments, the post-treatment process exposes the MOR layer 106 to a post-treatment gas mixture. The exposure enables the post-treatment gas mixture to interact with both the unexposed MOR regions 120 and the exposed MOR regions 125, but the post-treatment gas mixture interacts at a higher rate with the undesired MOR material and byproducts of the first regions (the unexposed MOR regions 120). Consequently, the post-treatment process helps modify the MOR layer 106 by removing bromine (Br) (or other remnants, scummings, or byproducts from the gas development step) from the MOR layer 106 which may have been introduced during previous processing steps. And by removing bromine (Br) (or other remnants, scummings, or byproducts from the gas development step), the post-treatment process may minimize or prevent outgassing from the substrate 100, which may be beneficial in subsequent transfers of the substrate 100 with other substrates.

In one or more embodiments, the post-treatment process comprises exposing the substrate 100 to a post-treatment gas mixture while maintaining the substrate 100 at a first temperature (or first processing temperature). The exposure of the substrate 100 to the post-treatment gas mixture adsorbs materials from the post-treatment gas mixture (such as HFAC) to the remaining portions of the unexposed MOR region 120 of the MOR layer 106 to chemically alter those regions, such as by forming chemically altered portions of the unexposed MOR region 120. After, the post-treatment chamber may be heated to a second temperature (or second processing temperature) to facilitate the removal of remnants and the chemically altered potions of the unexposed MOR region 120. As a result, the openings 135 now extend to the underlying layer 104 and the feature pattern of the patterned MOR mask 130 is more defined. In one or more embodiments, the post-treatment process may be performed in a separate processing chamber from a chamber used for the gas development step. In other embodiments, the post-treatment process may be performed in the same chamber used for the gas development step.

In various embodiments, the post-treatment gas mixture may chemically react with the remnants of the unexposed MOR region 120 in a self-limiting manner, such that only MOR material to a certain depth of the unexposed MOR region 120 is chemically altered. Consequently, the heating of the substrate 100 to the second temperature may only remove the chemically altered regions, which may only remove material to the depth associated with the self-limiting reactions. As a result, the post-treatment process may be performed cyclically to remove the remaining portions of the unexposed MOR region 120. Additionally, the post-treatment gas mixture may be selective to the unexposed MOR region 120 over the exposed MOR regions 125 such that the remaining MOR material in the unexposed MOR region 120 is removed at a different removal rate than the MOR material of the exposed MOR regions 125.

In an embodiment where the MOR layer 106 comprises tin (Sn) and bromine (Br), the post-treatment process may reduce the bromine content while leaving the tin content relatively constant, which results from the selectivity of the post-treatment gas mixture and process. Additionally, the post-treatment process, through the removal of remnants or other byproducts from the gas development process, reduces the outgassing from the substrate 100 (such as through the reduction in bromine content of the patterned MOR mask 130) which may minimize contamination of other substrates during a subsequent transfer to other processing chambers.

Various parameters of the post-treatment process may be controlled in real-time to improve the selectivity of the post-treatment process, to control removal rates of the chemically altered regions or portions of the unexposed MOR regions 120, and to prevent removing excess material from the patterned MOR mask 130. For example, in various embodiments, the post-treatment process may simultaneously control, monitor, and recursively update parameters such as gas flow rates, post-treatment gas mixture concentrations, partial pressures of the post-treatment gas mixture elements, chamber pressure of the post-treatment chamber, temperatures of the substrate 100, gas flow rates into the post-treatment chamber, and processing time of the post-treatment process or individual steps of the post-treatment process. For example, in one or more embodiments, the processing time may be between about 5 s and about 600 s.

In various embodiments, after performing the steps illustrated in FIGS. 1A-1E, subsequent processing steps may be performed to complete the device being fabricated from the substrate 100. For example, subsequent etching and depositing steps may be performed after transferring the substrate 100 to other processing chambers to finish forming the features from the feature pattern represented by the openings 135 in the patterned MOR mask 130. In various embodiments, the post-treatment processing parameters may be determined based on a scan of the substrate 100 after the gas development process, such as by using a light detector to measure the topology of the MOR layer 106. The processing method may then use that topology to determine amounts of remnants in undesired regions of the MOR layer 106 to form the patterned MOR mask 130 comprising an improved pattern fidelity.

In contrast to the negative tune MOR embodiment illustrated in FIGS. 1A-1E, FIGS. 2A-2B illustrate an embodiment of the processing method of this disclosure for a positive tune MOR. FIGS. 2A-2B may substitute the steps of the processing method illustrated and described using FIGS. 1B-1C, and after performing the steps of FIGS. 2A-2B, the processing method may resume with the steps illustrated and described using FIGS. 1D-1E.

FIG. 2A illustrates the same step as described for FIG. 1B, but for an embodiment where the substrate 100 comprises an MOR layer 206 comprising positive tune resist (positive tune MOR). The MOR layer 206 may be as described for the MOR layer 106, but configured in a positive tune format such that light exposure weakens the exposed regions. Similarly, a photo mask 208 may be as described for the photo mask 108 in FIG. 1B, but configured such that the opaque regions cover regions of the MOR layer 206 that are to remain after the gas development and post-treatment processes. The photolithography step illustrated in FIG. 2A exposes desired areas (or regions) of the MOR layer 206 to be removed to the light beams 110 to transfer a feature pattern into the MOR layer 206.

FIG. 2B illustrates the same step as described for FIG. 1C, but for an embodiment where the photolithography step of FIG. 2A forms a first region and a second region in the MOR layer 206, where the first region is an exposed MOR region 215 and the second region is an unexposed MOR region 210. And as a result of the substrate 100 comprising positive tune MOR, the exposure to the light beams 110 in FIG. 2A weakened the exposed MOR regions 215, which makes the exposed MOR regions 215 easier to remove in the subsequent gas development step, such as described used FIG. 1D above. After the step illustrated in FIG. 2B, the processing method may resume with the step described using FIG. 1D above, but the regions to be removed are the exposed MOR regions 215. The processing method described using FIGS. 1A-1E and FIGS. 2A-2B may be illustrated by the flowchart of FIG. 3.

FIG. 3 is a flowchart of a processing method 300 which uses a post-treatment step to remove remaining undesired portions of a developed MOR layer. The processing method 300 may begin in step 310. In step 310, the processing method 300 transfers the substrate to a gas development chamber. The substrate described in step 310 may be the substrate 100 described in FIG. 1C or in FIG. 2B, which is after a photolithography process has been performed to develop the MOR layer of the substrate.

In step 320, the processing method 300 performs a gas development process to remove desired regions of the MOR layer. In various embodiments where the MOR layer comprises positive tune resist, the gas development process removes exposed regions of the MOR layer (such as described using FIGS. 2A-2B). In other embodiments where the MOR layer comprises negative tune resist, the gas development process removes unexposed regions of the MOR layer (such as described using FIGS. 1A-1E).

Step 330 of the processing method 300 transfers the substrate to a post-treatment chamber to remove remnants or products of scumming as a result of the gas development process not fully removing the desired regions of the MOR layer. And step 340 of the processing method 300 performs a post-treatment process to remove remnants or products of scumming. In various embodiments, the post-treatment process may be the same as described using FIG. 1E above.

In other embodiments, step 340 may be performed in the same processing chamber as used in the gas development process of step 320. In those embodiments, step 330 may be optional, thus skipped and the processing method 300 may proceed from step 320 directly to step 340.

The post-treatment process of step 340 may use tailored gas mixtures to optimize chemical reactions to selectively remove remnants of the MOR layer left behind after the gas development process of step 320. For example, in various embodiments, the post-treatment process may expose the substrate to the tailored gas mixture for a processing time while maintaining a processing temperature of the substrate, and controlling flow rates, pressures, partial pressures, and other processing parameters of the post-treatment chamber and components of the gas mixture to selectively remove the undesired remnants of the MOR layer. For example, the gas mixture may be exposed to the substrate for a processing time at a first processing temperature, and then the chemically altered portions of the undesired remnants of the MOR layer may be removed by bringing the temperature to a second processing temperature.

In various embodiments, those various processing parameters of the post-treatment chamber may be controlled in real-time to further optimize the selectivity and removal rates of any remaining undesired portions of the MOR layer. Further, the post-treatment gas mixture may react with the remnants of the MOR layer desired to be removed in a self-limiting way, such that only chemically altered (or adsorbed) portions of the remnants are removed. As a result, outgassing from remnants of the MOR layer may be reduced, which also minimizes chances of potentially contaminating other substrates in a transfer process. An example post-treatment system comprising a post-treatment chamber which may be used to perform the post-treatment process of step 340 (or described using FIG. 1E) is described using FIG. 4 below.

FIG. 4 illustrates a schematic diagram of a post-treatment system 400, which is a processing system that may be used to perform the post-treatment process of this disclosure to remove remnants of undesired portions of the MOR layer after the gas development process, as described in previous figures. The post-treatment system 400 comprises several components designed to achieve precise control over the post-treatment process.

The post-treatment system 400 comprises a post-treatment chamber 410 which houses the main treatment components. In various embodiments, the post-treatment chamber 410 may be a processing chamber or a gas chamber configured to maintain a vacuum environment (or other process specifications) for the post-treatment process. Within the post-treatment chamber 410, a substrate holder 420 is positioned to support the substrate 100 during the post-treatment process. In various embodiments, the substrate holder 420 may comprise a heater (not shown) to control the temperature of the substrate 100 during the post-treatment process. In an embodiment, the substrate holder 420 comprises a resistive heater, where the heater (not shown) is the resistive heater. In other embodiments, the substrate holder 420 may comprise cooling elements to further control the temperature of the substrate 100 as desired during the post-treatment process. In some embodiments, the heating and cooling elements may be parts of the post-treatment chamber 410.

At the top of the post-treatment chamber 410 is a gas distribution system 430. The gas distribution system 430 comprises a gas inlet 432 for introducing post-treatment gases into the post-treatment chamber 410. Additionally, the post-treatment chamber 410 may comprise additional gas inlets besides the gas inlet 432. For example, as many gas inlets may be used as there are different gases for forming the gas mixture used in the post-treatment process. In some embodiments, as few as a single gas inlet may be used. In other embodiments, as many as ten gas inlets may be used.

The gas delivery of the post-treatment system 400 is controlled by a gas delivery system 440. This system manages the flow of various gases, such as a first gas 442, a second gas 444, and a third gas 446. In one or more embodiments, these gases are combined to form the gas mixture used for the post-treatment process of this disclosure. Additionally, the various first gas 442, second gas 444, and third gas 446 may comprise the various gases described above for the post-treatment gas mixture embodiments in FIGS. 1A-1E. In various embodiments, a purge gas may be provided by the gas delivery system 440, such as an inert gas used to purge the post-treatment chamber 410 during various steps of the post-treatment process. In various embodiments, the gas delivery system 440 may be configured to supply as many different gases as desired by the post-treatment process, such as by providing as few as a single gas, or as many as ten gases. For example, the many different gases (442, 444, and 446) may comprise inert gases such as Ar, N₂, or He.

In some embodiments, the post-treatment chamber 410 may comprise a remote plasma generator or remote radical generator configured to supply the post-treatment chamber 410 with excited, radical, or metastable species, or combinations thereof for use in the gas mixture of the post-treatment process. In those embodiments, a power source may be used by the plasma generator or the remote radical generator to generate the excited, radical, or metastable species, or combinations thereof. Further, the power source may be capable of supplying a source power between 500 W and 5000 W.

The temperature of the post-treatment process may be regulated by a temperature control system 460, which works in conjunction with the heating and cooling elements of the post-treatment chamber 410 or the substrate holder 420 to control the desired substrate temperature during the post-treatment process. For example, the temperature control system 460 may be capable of achieving temperatures during the post-treatment process within the post-treatment chamber 410 between about 35° C. and about 300° C. In various embodiments, the post-treatment chamber 410 can provide the first and second temperatures of the post-treatment process, where the first temperature is less than the second temperature, and both are between about 35° C. to about 300° C. In other embodiments, the post-treatment chamber 410 can provide the first and second temperatures of the post-treatment process, where the first temperature and the second temperature are the same temperature and greater than 100° C. In various embodiments, the substrate holder 420 may be any suitable substrate holder known in the art capable of holding the substrate 100 during the embodiment methods of this disclosure.

To control the pressure within the post-treatment chamber 410, the post-treatment system 400 comprises a vacuum pump 470 connected to the post-treatment chamber 410 through a gate valve 472. This setup allows for precise control of the chamber pressure during the post-treatment process. For example, the post-treatment process may configure pressures within the post-treatment chamber 410 using the vacuum pump 470 and the gate valve 472 between about 20 mTorr and about 90,000 mTorr.

The entire post-treatment system 400 may be managed by a controller 480, which may be coupled to a memory 485. The controller 480 coordinates the operation of all system components, while the memory 485 stores process recipes, parameters, and other relevant data of the post-treatment process and a previous gas development process. The controller 480 and the memory 485 may be any suitable conventional device known in the art and capable of performing the functions described above.

In one or more embodiments, the post-treatment system 400 is used to remove remnants or scumming products in undesired portions of an MOR layer left over from the gas development process. This is achieved by controlling various parameters in the post-treatment system 400, such as by using different flow rates for the gases from the gas delivery system 440, by using configurable and adjustable processing times during the exposure of the substrate 100 to the post-treatment gas mixture, by controlling the pressure of the post-treatment chamber 410 using the vacuum pump 470, by controlling the partial pressures of the gases used in the post-treatment gas mixture, by controlling the temperature of the substrate 100 or the post-treatment gas mixture using the temperature control system 460, or by optimally using different post-treatment gas mixtures by using different chemistries to selectively remove remnants or scumming products in undesired regions of the MOR layer. The gas delivery system 440 may also be capable of regulating partial pressures of the gases entering the post-treatment chamber 410 to be used as the post-treatment gas mixture.

The post-treatment system 400 enables the MOR layer of the substrate 100 to be developed such that there are not remnants in undesired portions of the MOR layer. Consequently, this may improve the quality (or fidelity) of the pattern of the MOR layer, improve the pattern transfer of the processing pattern developed in the MOR layer when used as a mask, and reduce the outgassing from the substrate 100. As an example, when the substrate 100 is transferred in a transfer apparatus (such as a FOUP) to other processing chambers in further processing steps for forming a particular electronic device, the substrate 100 may have reduced outgassing from the post-treatment process performed in the post-treatment system 400, and may not contaminate other substrates being transported in the same transfer apparatus.

By carefully controlling the gas flow rates through the different inlets, the post-treatment gas mixture characteristics, substrate temperature, partial pressures of the components of the post-treatment gas mixture, and chamber pressure, the post-treatment system 400 can selectively remove undesired portions of the MOR layer with precisely controlled post-treatment parameters. Further, the post-treatment process may be capable of tailoring the MOR layer to remove remnants or undesired portions of the MOR layer to achieve the feature pattern desired to have been achieved by a previous photolithography step.

In various embodiments, the gas distribution system 430 may be a showerhead gas injection system having a gas distribution assembly, and one or more gas distributions plates or conduits coupled to the gas distribution assembly and configured to form one or more gas distribution plenums or supply lines. In further embodiments, the gas distribution system 430 may comprise a branching gas distribution network designed to reduce or minimize gas distribution volume. The post-treatment system 400 may be used to implement various embodiment post-treatment methods of this disclosure, such as in the post-treatment process or processing methods described below using the flowcharts of FIGS. 5-6. Additionally, the post-treatment system 400 may be capable of implementing the post-treatment process as previously described using FIGS. 1D-1E, and FIG. 3 above. In other embodiments, the post-treatment system 400 may be capable of performing both the post-treatment process described using FIGS. 1D-1E and the gas development process described using FIGS. 1C-1D above.

FIGS. 5-6 are flowcharts illustrating example methods of processing a substrate in accordance with embodiments of the disclosure. The methods of FIGS. 5-6 may be combined with other methods and performed using the systems and apparatuses as described herein. For example, the methods of FIGS. 5-6 may be implemented in the post-treatment system 400 of FIG. 4. Although shown in a logical order, the arrangement and numbering of the steps of FIGS. 5-6 are not intended to be limiting.

Referring to FIG. 5, step 510 of a method 500 of processing a substrate receives the substrate comprising a metal oxide photoresist (MOR) layer disposed over an underlying layer, the MOR layer comprising a first region and a second region. In various embodiments, the first region may correspond to the unexposed MOR regions 120 of FIGS. 1A-1E and the second region may correspond to the exposed MOR regions 125 of FIGS. 1A-1E. In other embodiments, the first region may be the exposed MOR regions 215 of FIGS. 2A-2B and the second region may be the unexposed MOR regions 210 of FIGS. 2A-2B. After, the method 500 performs a gas development treatment on the MOR layer to remove portions of the first region in step 520. In step 520, the gas development treatment uses gases to remove portions of the first regions of the MOR layer to develop the MOR layer for use as an etch mask. In various embodiments, the gas development treatment may be the gas development process described using FIG. 1D above, or as step 320 of the processing method 300 in FIG. 3.

Step 530 of the method 500 exposes the MOR layer to a gas mixture to remove remaining portions of the first region after the gas development treatment, to improve pattern fidelity of a feature pattern in the MOR layer by removing remaining portions, and to form a patterned MOR mask. In various embodiments, step 530 may be as described for step 340 of the processing method 300 of FIG. 3, and step 530 may be referred to as a post-treatment process.

Further, in various embodiments, the substrate of the method 500 may be the substrate 100 of FIGS. 1A-1E and FIGS. 2A-2B. Similarly, the underlying layer may be the underlying layer 104, the MOR layer may be the MOR layer 106 of FIGS. 1A-1E or the MOR layer 206 of FIGS. 2A-2B, the first region may be the unexposed MOR regions 120 or the exposed MOR regions 215 of the MOR layer 106 or the MOR layer 206, the second regions may be the exposed MOR region 125 or the unexposed MOR regions 210, and the patterned MOR mask may be the patterned MOR mask 130. In various embodiments, the feature pattern may be formed by the openings 135 of the substrate 100 in FIG. 1E.

Now referring to FIG. 6, step 610 of a method 600 of processing a substrate receives the substrate in a processing chamber, the substrate comprising a MOR layer disposed over an underlying layer, the substrate having been treated in a gas development process, the MOR layer comprising a first region and a second region.

In various embodiments, the gas development process may be the gas development process described using FIG. 1C or the gas development process described in step 320 of FIG. 3. Additionally, the processing chamber may be the post-treatment chamber 410 of the post-treatment system 400 of FIG. 4, and the method 600 may be performed in the post-treatment system 400. Further, the substrate of the method 600 may be the substrate 100 of FIGS. 1A-1E or FIGS. 2A-2B above. Similarly, the underlying layer may be the underlying layer 104 and the MOR layer may be the MOR layer 106 of FIGS. 1A-1E or the MOR layer 206 of FIGS. 2A-2B.

After, in step 620, the method 600 sets the processing chamber to a processing pressure and heats the substrate to a first processing temperature, which may be specified by a processing recipe. In an embodiment, the heating may be performed using the temperature control system 460 of FIG. 4. Step 630 of the method 600 exposes the MOR layer to a gas mixture by flowing the gas mixture into the processing chamber at a flow rate for a processing time, the gas mixture adsorbing to the first region of the MOR layer to form a chemically altered first region. And the method 600, in step 640, heats the substrate to a second processing temperature to remove the chemically altered first region and form a patterned MOR mask. In one or more embodiments, the second processing temperature may be greater than the first processing temperature. In other embodiments, the second processing temperature may be the same as the first processing temperature, where both processing temperatures are over 100° C. In various embodiments, the patterned MOR mask may be the patterned MOR mask 130 of FIG. 1E and the patterned MOR mask may now comprise a feature pattern which may be the openings 135 of FIG. 1E.

The processing method 600 may be the post-treatment process described for step 340 of FIG. 3 above. Further, the processing method 600 may be the post-treatment process described using FIGS. 1D-1E for the substrate 100. Similar to the processing method 500 of FIG. 5, in the processing method 600 of FIG. 6 the first region may be the unexposed MOR region 120 and the second region may be the exposed MOR regions 125 of FIGS. 1A-1E in various embodiments. In other embodiments, the first region may be the exposed MOR region 215 and the second region may be the unexposed MOR regions 210 of FIGS. 2A-2B.

Example embodiments of the invention are described below. Other embodiments can also be understood from the entirety of the specification as well as the claims filed herein.

Example 1. A method for processing a substrate includes receiving the substrate including a metal oxide photoresist (MOR) layer disposed over an underlying layer, the MOR layer including a first region and a second region. The method further includes performing a gas development treatment on the MOR layer to remove portions of the first region. And the method further includes exposing the MOR layer to a gas mixture to remove remaining portions of the first region after the gas development treatment to form a patterned MOR mask.

Example 2. The method of example 1, where the MOR layer includes positive tune MOR, the first region includes MOR exposed to patterning light, and the second region includes MOR unexposed to patterning light.

Example 3. The method of one of examples 1 or 2, where the MOR layer includes negative tune MOR, the first region includes MOR unexposed to patterning light, and the second region includes MOR exposed to patterning light.

Example 4. The method of one of examples 1 to 3, where the gas mixture includes a chelating agent including oxygen as a coordinating atom.

Example 5. The method of one of examples 1 to 4, where the MOR layer includes tin (Sn), oxygen (O), or organic components.

Example 6. The method of one of examples 1 to 5, where the exposing the MOR layer to the gas mixture to remove remaining portions of the first region after the gas development treatment includes heating the substrate to a first processing temperature, and flowing the gas mixture over the substrate at a flow rate for a processing time, the gas mixture including a plurality of gases, the substrate at the first processing temperature, the gas mixture adsorbing to the remaining portions of the first region of the MOR layer and chemically altering the remaining portions to form chemically altered portions of the first region. And the exposing further includes heating the substrate to a second processing temperature to remove the chemically altered portions of the first region.

Example 7. The method of one of examples 1 to 6, where the first processing temperature and the second processing temperature are between 35° C. and 300° C., where the processing time is between 5 s and 600 s, and where a processing pressure is between 20 mTorr and 90,000 mTorr.

Example 8. The method of one of examples 1 to 7, further includes transferring the substrate to an etching chamber, and etching the substrate to transfer a feature pattern of the patterned MOR mask to the underlying layer of the substrate using the patterned MOR mask as an etch mask.

Example 9. The method of one of examples 1 to 8, where each gas of the plurality of gases of the gas mixture corresponds to an associated partial pressure.

Example 10. A method for processing a substrate includes receiving the substrate in a processing chamber, the substrate including a metal oxide photoresist (MOR) layer disposed over an underlying layer, the substrate having been treated in a gas development process, the MOR layer including a first region and a second region. The method further includes setting the processing chamber to a processing pressure and heating the substrate to a first processing temperature, and exposing the MOR layer to a gas mixture by flowing the gas mixture into the processing chamber at a flow rate for a processing time, the gas mixture adsorbing to the first region of the MOR layer to form a chemically altered first region. And the method further includes heating the substrate to a second processing temperature to remove the chemically altered first region and form a patterned MOR mask, the second processing temperature being greater than the first processing temperature.

Example 11. The method of example 10, where the MOR layer includes positive tune MOR, the first region includes MOR exposed to patterning light, and the second region includes MOR unexposed to patterning light.

Example 12. The method of one of examples 10 or 11, where the MOR layer includes negative tune MOR, the first region includes MOR unexposed to patterning light, and the second region includes MOR exposed to patterning light.

Example 13. The method of one of examples 10 to 12, where the first processing temperature and second processing temperature are between 35° C. and 300° C., where the processing pressure is between 20mTorr and 90,000 mTorr, and where the processing time is between 5 s and 600 s.

Example 14. The method of one of examples 10 to 13, where the gas mixture includes a chelating agent including oxygen as a coordinating atom.

Example 15. The method of one of examples 10 to 14, where the flow rate of the gas mixture, the processing time, the processing pressure, the first processing temperature, and the second processing temperature are adjusted in real-time to control a removal rate of the first region.

Example 16. The method of one of examples 10 to 15, where the first region includes remnants that remained after the gas development process, or scumming products from the gas development process, and where the MOR layer includes tin (Sn), oxygen (O), or organic components.

Example 17. The method of one of examples 10 to 16, where partial pressures of gases of the gas mixture are adjusted in real-time to control a removal rate of the first region.

Example 18. A system for processing a substrate includes a substrate holder disposed in a processing chamber, a vacuum pump, a gas distribution system, a temperature control system coupled to the substrate holder, and a controller coupled to the gas distribution system, the vacuum pump, the temperature control system, and a memory storing instructions to be executed by the controller. The instructions when executed cause the controller to receive the substrate on the substrate holder, the substrate including a MOR layer disposed over an underlying layer, the substrate having been treated in a gas development process, the MOR layer including a first region and a second region, and set the processing chamber to a processing pressure using the vacuum pump and heating the substrate to a first processing temperature using the temperature control system. The instructions when executed further cause the controller to expose the MOR layer to a gas mixture by flowing the gas mixture into the processing chamber at a flow rate for a processing time using the gas distribution system, the gas mixture adsorbing to the first region of the MOR layer to form a chemically altered first region, and heat the substrate to a second processing temperature using the temperature control system to remove the chemically altered first region and form a patterned MOR mask.

Example 19. The system of example 18, where the temperature control system includes a resistive heater.

Example 20. The system of one of examples 18 or 19, where the gas distribution system includes a showerhead gas injection system including a gas distribution assembly.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
receiving the substrate comprising a metal oxide photoresist (MOR) layer disposed over an underlying layer, the MOR layer comprising a first region and a second region;
performing a gas development treatment on the MOR layer to remove portions of the first region; and
exposing the MOR layer to a gas mixture to remove remaining portions of the first region after the gas development treatment to form a patterned MOR mask.

2. The method of claim 1, wherein the MOR layer comprises positive tune MOR, the first region comprises MOR exposed to patterning light, and the second region comprises MOR unexposed to patterning light.

3. The method of claim 1, wherein the MOR layer comprises negative tune MOR, the first region comprises MOR unexposed to patterning light, and the second region comprises MOR exposed to patterning light.

4. The method of claim 1, wherein the gas mixture comprises a chelating agent comprising oxygen as a coordinating atom.

5. The method of claim 1, wherein the MOR layer comprises tin (Sn), oxygen (O), or organic components.

6. The method of claim 1, wherein the exposing the MOR layer to the gas mixture to remove remaining portions of the first region after the gas development treatment comprises:
heating the substrate to a first processing temperature;
flowing the gas mixture over the substrate at a flow rate for a processing time, the gas mixture comprising a plurality of gases, the substrate at the first processing temperature, the gas mixture adsorbing to the remaining portions of the first region of the MOR layer and chemically altering the remaining portions to form chemically altered portions of the first region; and
heating the substrate to a second processing temperature to remove the chemically altered portions of the first region.

7. The method of claim 6, wherein the first processing temperature and the second processing temperature are between 35° C. and 300° C., wherein the processing time is between 5 s and 600 s, and wherein a processing pressure is between 20 mTorr and 90,000 mTorr.

8. The method of claim 6, further comprising:
transferring the substrate to an etching chamber; and
etching the substrate to transfer a feature pattern of the patterned MOR mask to the underlying layer of the substrate using the patterned MOR mask as an etch mask.

9. The method of claim 6, wherein each gas of the plurality of gases of the gas mixture corresponds to an associated partial pressure.

10. A method for processing a substrate, the method comprising:
receiving the substrate in a processing chamber, the substrate comprising a metal oxide photoresist (MOR) layer disposed over an underlying layer, the substrate having been treated in a gas development process, the MOR layer comprising a first region and a second region;
setting the processing chamber to a processing pressure and heating the substrate to a first processing temperature;
exposing the MOR layer to a gas mixture by flowing the gas mixture into the processing chamber at a flow rate for a processing time, the gas mixture adsorbing to the first region of the MOR layer to form a chemically altered first region; and
heating the substrate to a second processing temperature to remove the chemically altered first region and form a patterned MOR mask, the second processing temperature being greater than the first processing temperature.

11. The method of claim 10, wherein the MOR layer comprises positive tune MOR, the first region comprises MOR exposed to patterning light, and the second region comprises MOR unexposed to patterning light.

12. The method of claim 10, wherein the MOR layer comprises negative tune MOR, the first region comprises MOR unexposed to patterning light, and the second region comprises MOR exposed to patterning light.

13. The method of claim 10, wherein the first processing temperature and second processing temperature are between 35° C. and 300° C., wherein the processing pressure is between 20 mTorr and 90,000 mTorr, and wherein the processing time is between 5 s and 600 s.

14. The method of claim 10, wherein the gas mixture comprises a chelating agent comprising oxygen as a coordinating atom.

15. The method of claim 10, wherein the flow rate of the gas mixture, the processing time, the processing pressure, the first processing temperature, and the second processing temperature are adjusted in real-time to control a removal rate of the first region.

16. The method of claim 10, wherein the first region comprises remnants that remained after the gas development process, or scumming products from the gas development process, and wherein the MOR layer comprises tin (Sn), oxygen (O), or organic components.

17. The method of claim 10, wherein partial pressures of gases of the gas mixture are adjusted in real-time to control a removal rate of the first region.

18. A system for processing a substrate, the system comprising:
a substrate holder disposed in a processing chamber;
a vacuum pump;
a gas distribution system;
a temperature control system coupled to the substrate holder; and
a controller coupled to the gas distribution system, the vacuum pump, the temperature control system, and a memory storing instructions to be executed by the controller, the instructions when executed cause the controller to:
receive the substrate on the substrate holder, the substrate comprising a MOR layer disposed over an underlying layer, the substrate having been treated in a gas development process, the MOR layer comprising a first region and a second region;
set the processing chamber to a processing pressure using the vacuum pump and heating the substrate to a first processing temperature using the temperature control system;
expose the MOR layer to a gas mixture by flowing the gas mixture into the processing chamber at a flow rate for a processing time using the gas distribution system, the gas mixture adsorbing to the first region of the MOR layer to form a chemically altered first region; and
heat the substrate to a second processing temperature using the temperature control system to remove the chemically altered first region and form a patterned MOR mask.

19. The system of claim 18, wherein the temperature control system comprises a resistive heater.

20. The system of claim 18, wherein the gas distribution system comprises a showerhead gas injection system comprising a gas distribution assembly.
